(19) United States
(12) Patent Application Publication
(10) Pub. No.: US 2008/0048325 A1
(43) Pub. Date: Feb. 28, 2008

(54) Semiconductor device and fabricating method thereof

(76) Inventor: Jae-Won Han, Gyeongi-do (KR)

Correspondence Address: SHERR & NOURSE, PLLC, 620 HERNDON PARKWAY, SUITE 200, HERNDON, VA, 20170, US

(21) Appl. No.: 11/841,102

(22) Filed: Aug. 20, 2007

(30) Foreign Application Priority Data
Aug. 23, 2006 (KR) 10-2006-0080121

(51) Int. Cl. H01L 23/48; H01L 21/60

(52) U.S. Cl. 257/751; 438/106; 257/E23.01; 257/E21.506

(57) ABSTRACT

A method of effectively fabricating a semiconductor device involves separately fabricating a first substrate having a transistor layer and a second substrate having a metal wire layer, and stacking the first and second substrates. A transistor on the first substrate is electrically connected to a metal wire on the second substrate through a connection electrode.

The present application claims priority under 35 U.S.C. 119 to Korean Patent Application No. 10-2006-0080121, filed on Aug. 23, 2006, which is hereby incorporated by reference in its entirety.

### BACKGROUND

A semiconductor device fabrication process may be generally divided into two processes. First is a process for forming a transistor layer, such as a substrate fabrication process or a front end of line (FEOL) fabrication process. Second is a process for forming a metal wire, such as a wiring process or a back end of line (BEOL) fabrication process.

The complete process involves preparing a semiconductor substrate, a process for forming a transistor on a silicon wafer, and a process for connecting and insulating a meal electrode wire. When these processes are performed sequentially on a silicon wafer, the production of a completed device becomes very time consuming.

### SUMMARY

Embodiments provide a semiconductor device and a simplified fabrication method for improving yield.

In embodiments, a semiconductor device may include a first substrate including a transistor layer having at least one transistor. A second substrate may include a metal wire layer having at least one metal wire. A connection electrode may be used for electrically connecting the transistor of the first substrate to the metal wire of the second substrate.

In embodiments, a method of fabricating a semiconductor device includes forming a first substrate having a transistor layer with a transistor. A second substrate is having a metal wire layer having a metal wire is formed. The second substrate is stacked on the first substrate, electrically connecting the transistor to the metal wire.

### DRAWINGS

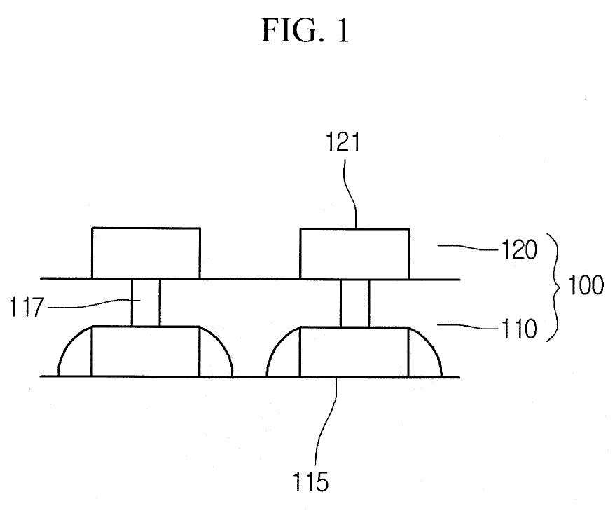

Example FIG. 1 is a diagram illustrating a substrate having a transistor layer formed by a semiconductor device fabrication method according to embodiments.

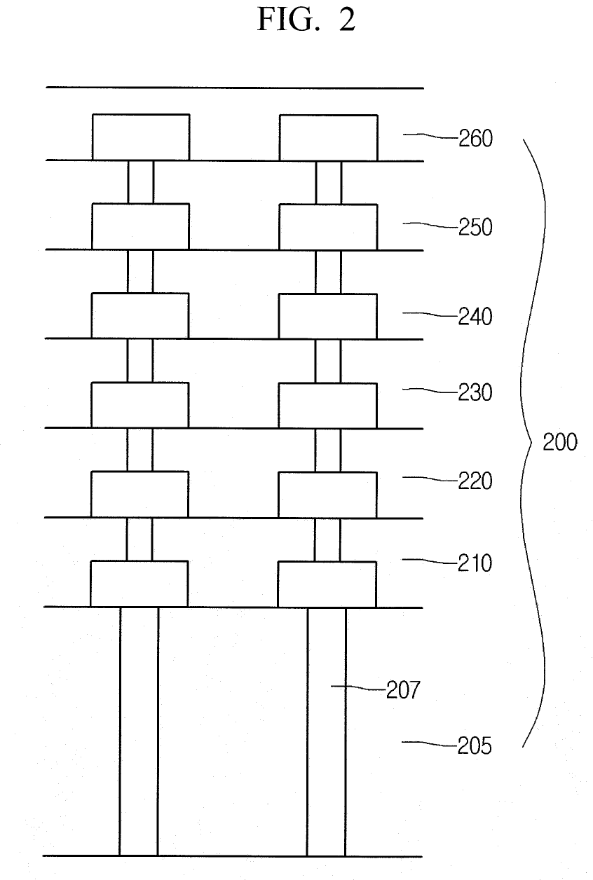

Example FIG. 2 is a diagram illustrating a substrate having a metal wire layer formed by a semiconductor device fabrication method according to embodiments.

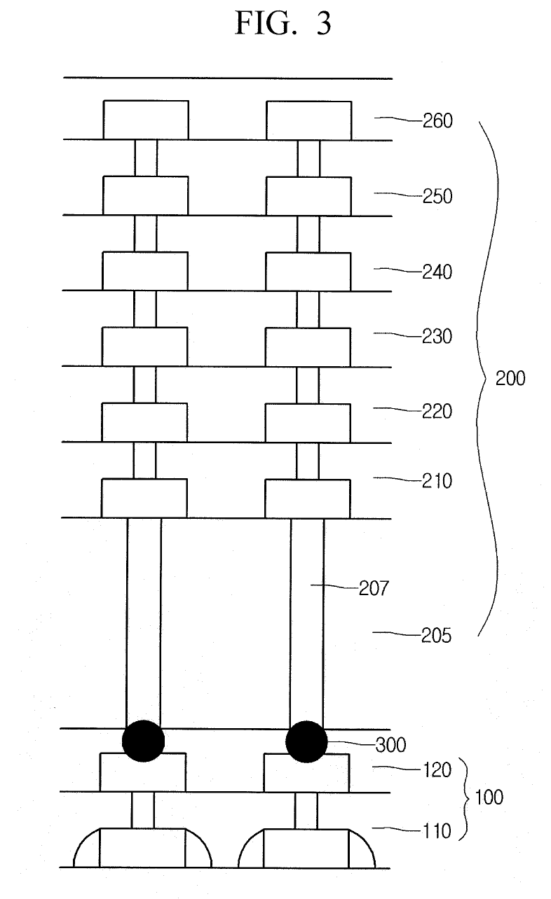

Example FIG. 3 is a diagram illustrating a semiconductor device having a transistor layer and a metal wire layer, formed by a semiconductor device fabrication method according to embodiments.

### DESCRIPTION

Embodiments introduce a method of effectively fabricating a semiconductor device by separately fabricating a first substrate having a transistor layer and a second substrate having a metal wire layer, and stacking the first and second substrates. A transistor on the first substrate is electrically connected to a metal wire on the second substrate through a connection electrode.

As shown in example FIG. 1, a first substrate 100 having a transistor layer 110 and a metal wire layer 120 is fabricated by the method according to embodiments. A transistor 115 is formed in the transistor layer 110. The transistor 115 may be electrically connected to a metal wire 121 of the metal wire layer 120 by a contact plug 117.

Although example FIG. 1 shows one metal wire layer 120 over the transistor layer 110, a plurality of metal wire layers may be formed according to other embodiments of the method. Alternatively, the process for fabricating the first substrate 100 may continue only to the formation of contact plug 117.

As shown in example FIG. 2, a second substrate 200 having a semiconductor substrate 205, a penetration electrode 207, a first metal wire layer 210, a second metal wire layer 220, a third metal wire layer 230, a fourth metal wire layer 240, a fifth metal wire layer 250, and a sixth metal wire layer 260 is fabricated by the method according to embodiments.

The first, second, third, fourth, fifth, and sixth metal wire layers 210 to 260 may form a wire or wires for processing signals. Although example FIG. 2 shows six metal wire layers 210 to 260 in an exemplary embodiment, the number of the metal wire layers may increase or decrease according to design requirements.

Hereinafter, a process of fabricating the second substrate 200 will be described. At first, a penetration electrode 207 may be formed to penetrate the semiconductor substrate 205. The penetration electrode 207 may be formed by sequentially performing a patterning process, an etching process, a metal forming process, and a chemical mechanical polishing (CMP) process over the semiconductor substrate 205.

The penetration electrode 207 may be made of a material selected from the group consisting of W, Cu, Al, Ag, and Au. The penetration electrode 207 may be deposited through a chemical vapor deposition (CVD) process, a physical vapor deposition (PVD) process, an evaporation process, and an electrochemical planting (ECP) process. Also, TaN, Ta, TiN, Ti, and/or TiSiN may be used as a barrier metal for the penetration electrode 207. The barrier metal may be formed through a CVD process, a PVD process, and/or an atomic layer deposition (ALD) process. The penetration electrode may be exposed on a surface of semiconductor substrate 205.

At least one metal wire layer is formed over the semiconductor substrate 205. The metal wire layer electrically connects the lowest metal wire of the metal wire layer over the semiconductor substrate 205 to the penetration electrode 207. Various metal wire layer forming methods, such as a damascene process, may be used.

The metal wire may be made of a material selected from the group consisting of W, Cu, Al, μg, and Au. The metal wire may be deposited through a CVD process, a PVD process, an evaporation process, and/or an ECP process. Also, TaN, Ta, TiN, Ti, and TiSiN may be used as a barrier metal for the metal wire. The barrier metal may be formed through a CVD process, a PVD process, and an/or an ALD process. At least one metal wire layer may be formed over the semiconductor substrate 205 at first, and the penetration electrode 207 may be formed to penetrate the semiconductor substrate 205 to connect to a metal wire according to embodiments.

As shown in FIG. 3, after the first substrate 100 and the second substrate 200 are fabricated as described above, the first and second substrates 100 and 200 may be stacked together. The semiconductor device according to embodiments may include a first substrate 100, a second substrate 200, and a connection electrode 300. The connection electrode 300 may connect a transistor of the first substrate 100 and a metal wire of the second substrate 200. The connection electrode 300 may be electrically connected to the metal wire of the second substrate 200 through the penetration electrode 207 of the second substrate 200. The connection electrode 300 may be connected to the transistor of the first substrate 100.

A method for fabricating a semiconductor device using a system in a package according to embodiments may have the following advantages. In the fabrication method according to embodiments, a first substrate fabrication process and a second substrate fabricating process may be performed separately. This may prevent the first substrate having the transistor layer from being discarded because of errors or faults in the second substrate fabrication process for a metal wire layer.

Since a metal wire layer fabrication process such as a back end of line (BEOL) process may be performed separately from a transistor layer fabrication process such as a front end of line (FEOL) process according to embodiments, a transistor layer can be produced that is not influenced by the metal layer fabrication process.

Since the metal wire layer may be fabricated separately, it may be possible to select processes with a wider temperature range for performing thermal processes. The semiconductor device and the fabricating method thereof can simplify a fabricating process and improve a fabrication yield.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a first semiconductor substrate comprising a transistor layer, wherein the transistor layer comprises at least one transistor;
a second semiconductor substrate comprising a metal wire layer, wherein the metal wire layer comprises at least one metal wire; and
a connection electrode electrically connecting said at least one transistor to said at least one metal wire.

2. The apparatus of claim 1, wherein the first substrate comprises a semiconductor device having a metal wire layer over the transistor layer.

3. The apparatus of claim 1, wherein the first substrate comprises a contact plug connected to the transistor.

4. The apparatus of claim 1, wherein the second substrate comprises a penetration electrode connected to the metal wire, wherein the penetration electrode penetrates the second semiconductor substrate.

5. The apparatus of claim 4, wherein at least one of the metal wire and the penetration electrode comprise at least one of W, Cu, Al, Ag, and Au.

6. The apparatus of claim 4, wherein the connection electrode is electrically connected to the metal wire of the second substrate through the penetration electrode.

7. The apparatus of claim 4, wherein the penetration electrode is exposed on a surface of the second semiconductor substrate.

8. The apparatus of claim 4, comprising at least one of TaN, Ta, TiN, Ti, and TiSiN formed as a barrier metal for the penetration electrode.

9. The apparatus of claim 1, comprising at least one of TaN, Ta, TiN, Ti, and TiSiN formed as a barrier metal for the metal wire.

10. A method comprising:
forming a first semiconductor substrate comprising a transistor layer, wherein the transistor layer comprises at least one transistor;
forming a second semiconductor substrate comprising a metal wire layer, wherein the metal wire layer comprises at least one metal wire; and
stacking the second semiconductor substrate over the first semiconductor substrate, wherein said stacking comprises electrically connecting said at least one transistor to said at least one metal wire.

11. The method of claim 10, wherein said at least one transistor and said at least one metal wire are electrically connected through at least one connection electrode.

12. The method of claim 10, wherein the forming of the first semiconductor substrate comprises forming a metal wire layer over the transistor layer.

13. The method of claim 10, wherein the forming of the first semiconductor substrate comprises forming a contact plug connected to the transistor.

14. The method of claim 10, wherein said forming of the second semiconductor substrate comprises:
forming a penetration electrode penetrating the second semiconductor substrate; and
forming a metal wire over the second semiconductor substrate connected to the penetration electrode.

15. The method of claim 11, wherein the forming of the second substrate includes:
forming a metal wire over a semiconductor substrate; and
forming a penetration electrode penetrating the semiconductor substrate and connected to the metal wire.

16. The method of claim 15, wherein the connection electrode is electrically connected to the metal wire through the penetration electrode.

17. The method of claim 16, wherein the penetration electrode is exposed on a surface of the second semiconductor substrate.

18. The method of claim 11, wherein the metal wire and the penetration electrode comprise at least one of W, Cu, Al, Ag, and Au.

19. The method of claim 14, comprising forming a barrier metal for the penetration electrode comprising at least one of TaN, Ta, TiN, Ti, and TiSiN.

20. The method of claim 11, comprising forming a barrier metal for the metal wire using at least one of TaN, Ta, TiN, Ti, and TiSiN.
